(19) United States
(12) Patent Application Publication
(10) Pub. No.: US 2025/0370181 A1
(43) Pub. Date: Dec. 4, 2025

(54) SYSTEM AND METHODS FOR INTEGRATED EPIC ARCHITECTURE

(71) Applicant: Samsung Electronics Co., Ltd., Suwon-si (KR)

(72) Inventors: Yibing Michelle WANG, Temple City, CA (US); Tze Ching FUNG, Diamond Bar, CA (US); Eunchul KANG, South Pasadena, CA (US)

(21) Appl. No.: 18/826,166

(22) Filed: Sep. 5, 2024

Related U.S. Application Data
(60) Provisional application No. 63/653,205, filed on May 29, 2024.

(51) Int. Cl. G02B 6/12; G02B 6/42

(52) U.S. Cl. CPC G02B 6/12004; G02B 6/12007; G02B 6/4201

(57) ABSTRACT

A device includes a photonic integrated circuit, an optical demultiplexer, and an electronic integrated circuit. The electronic integrated circuit is mounted on the photonic integrated circuit and includes at least one photodetector optically coupled to the optical demultiplexer. The optical demultiplexer separates an incoming optical signal into a first separated optical signal and a second separated optical signal. The at least one photodetector has a first photodetector and a second photodetector. The first photodetector receives the first separated optical signal, and the second photodetector receives the second separated optical signal.

### CROSS-REFERENCE TO RELATED APPLICATION

This application claims the priority benefit under 35 U.S.C. § 119 (e) of U.S. Provisional Application No. 63/653,205 filed on May 29, 2024, the disclosure of which is incorporated herein by reference in its entirety.

### TECHNICAL FIELD

The subject matter disclosed herein relates to packaging. More particularly, the subject matter disclosed herein relates to a technique for connecting between electronic integrated circuits (EICs) and photonic integrated circuits (PICs).

### BACKGROUND

Semiconductor devices may connect to additional devices and circuitry on different substrates. Forming connections between substrates may provide increased computational power. However, forming connections between substrates may cause difficulties. Packaging describes the general method for connecting and integrating multiple computational components together in an integrated unit and may involve multiple different types of integrated circuits on multiple substrates which may combine into a single unit. Packaging may also describe a method for which multiple computational components within a single unit are protected by the use of various techniques to provide thermal, physical and electrical protection It is further noted that background concepts discussed herein are for informational purposes only and are not intended to limit the present disclosure. Nor should the background or field described herein be intended to limit the disclosure herein to a particular use or concept.

### SUMMARY

In an exemplary embodiment, a device includes a photonic integrated circuit, an optical demultiplexer, and an electronic integrated circuit. The electronic integrated circuit is mounted on the photonic integrated circuit and includes at least one photodetector optically coupled to the optical demultiplexer. The optical demultiplexer separates an incoming optical signal into a first separated optical signal and a second separated optical signal. The at least one photodetector may have a first photodetector and a second photodetector. The first photodetector receives the first separated optical signal, and the second photodetector receives the second separated optical signal. In some embodiments, the optical demultiplexer separates the optical signal into the first separated optical signal and the second separated optical signal by polarization. In some embodiments, the optical demultiplexer separates the optical signal into the first separated optical signal and the second separated optical signal by wavelength. In some embodiments, the optical demultiplexer separates the optical signal into the first separated optical signal and the second separated optical signal by optical fiber mode. In some embodiments, the electronic integrated circuit includes a plug connector to receive an incoming optical fiber which transmits an incoming optical signal to the optical demultiplexer. In some embodiments, the photonic integrated circuit includes a plug connector for a bi-directional optical fiber, the bi-directional optical fiber transmitting the incoming optical signal to the optical demultiplexer and the bi-directional optical fiber transmitting an outgoing optical signal from the photonic integrated circuit. In some embodiments, the optical demultiplexer is mounted on the photonic integrated circuit and the optical demultiplexer may transmit the incoming optical signal to at least one photodetector on the electronic integrated circuit using an optical via. In some embodiments, the optical demultiplexer may be mounted on the electronic integrated circuit, and the optical demultiplexer is configured to transmit the incoming optical signal to at least one photodetector upon a divergence path.

In an exemplary embodiment, a system includes a substrate with an electronic integrated circuit and a photonic integrated circuit both mounted upon the substrate. The photonic integrated circuit may have an optical transceiver, an optical demultiplexer, a photodetector and at least part of an amplifier. In some embodiments, an optical transceiver may transmit an outgoing optical signal and receive an incoming optical signal. In some embodiments, the optical demultiplexer may demultiplex the incoming optical signal into a demultiplexed optical signal. In some embodiments, the photodetector may generate a first electrical signal from the demultiplexed optical signal and transmit the first electrical signal to the at least first portion of the amplifier, the at least first portion of the amplifier generating a second electrical signal. In some embodiments, the electronic integrated circuit may receive the second electrical signal. In some embodiments, the at least first portion of the amplifier may include input resistors or first stage resistors, with the second electrical signal including a bias voltage or signal voltage. In some embodiments, the optical demultiplexer may have a first nanostructured layer to separate the incoming optical signal into a first optical signal and a second optical signal. In some embodiments, the first optical signal and the second optical signal may be separated by one or more of wavelength, polarization and mode. In some embodiments, the at least first portion of the amplifier may be formed in the photonic device layer of the photonic integrated circuit. In some embodiments, the at least first portion of the amplifier may be a transimpedance amplifier formed within the photonic device layer of the photonic integrated circuit and the second electrical signal may be an amplified signal. In some embodiments, the optical demultiplexer may demultiplex the incoming optical signal into a first optical signal and a second optical signal, with a first photodetector receiving the first optical signal and in turn generating a third electrical signal, with a second photodetector receiving the second optical signal and in turn generating a fourth electrical signal. In some embodiments, the at least first portion of the amplifier may include a first at least first portion of the amplifier to receive the third electrical signal and generate a fifth electrical signal, and a second at least first portion of the amplifier to receive the fourth electrical signal and generate a sixth electrical signal, with the electronic integrated circuit receiving the fifth electrical signal and the sixth electrical signal. In some embodiments, the electronic integrated circuit may include a second portion of the amplifier, with the at least first portion of the amplifier and the second portion of the amplifier forming a transimpedance amplifier.

According to an exemplary embodiment, a device may include a substrate having an electronic integrated circuit and photonic integrated circuit mounted upon. The photonic integrated circuit may include an optical demultiplexer, a photodetector, and a transimpedance amplifier. The optical demultiplexer may receive an incoming optical signal and split the incoming optical signal into a demultiplexed optical signal. The photodetector may generate an electrical signal from the demultiplexed optical signal, and transmit the electrical signal to the transimpedance amplifier to generate an amplified signal, with the electronic integrated circuit receiving the amplified signal. In some embodiments, the optical demultiplexer may split the demultiplexed optical signal by polarization. In some embodiments, the optical demultiplexer may split the demultiplexed optical signal by wavelength. In some embodiments, the optical demultiplexer may split the demultiplexed optical signal by optical fiber mode. In some embodiments, the transimpedance amplifier is formed in the photonic device layer of the photonic integrated circuit.

### BRIEF DESCRIPTION OF THE DRAWING

In the following section, the aspects of the subject matter disclosed herein will be described with reference to exemplary embodiments illustrated in the figures, in which:

FIG. 1 depicts a plan view of an example embodiment of a hybrid electronic integrated circuit and photonic integrated circuit system architecture according to various embodiments of the subject matter disclosed herein;

FIG. 2 depicts a plan view of an example embodiment of a hybrid electronic integrated circuit and photonic integrated circuit system architecture according to various embodiments of the subject matter disclosed herein;

FIG. 3 depicts plan view of an example embodiment of an electronic integrated circuit according to various embodiments of the subject matter disclosed herein;

FIG. 4 depicts a cross-sectional view of an example embodiment of a first monolithic hybrid transceiver according to various embodiments of the subject matter disclosed herein;

FIG. 5 depicts a cross-sectional view of an example embodiment of a second monolithic hybrid transceiver according to various embodiments of the subject matter disclosed herein; and

FIG. 6 depicts a plan view of an example embodiment of a third monolithic hybrid transceiver according to various embodiments of the subject matter disclosed herein;

FIG. 7 depicts a cross-sectional view of an example embodiment of the third monolithic hybrid coupler according to various embodiments of the subject matter disclosed herein;

FIG. 8 depicts a plan view of an example embodiment of a fourth monolithic hybrid transceiver according to various embodiments of the subject matter disclosed herein; and

FIG. 9 depicts a cross-sectional view of an example embodiment of the fourth monolithic hybrid transceiver according to various embodiments of the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” etc.) may be occasionally interchangeably used with a corresponding non-hyphenated version (e.g., “two dimensional,” “predetermined, etc.), and a capitalized entry (e.g., “Integrated Chip,” “First Substrate,” “PIC,” etc.) may be interchangeably used with a corresponding non-capitalized version (e.g., “integrated chip,” “first substrate,” “pic,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Disclosed herein are various devices, structures and methods for forming an optical interconnection between devices including both electronic integrated circuits (EICs) and photonic integrated circuits (PICs). In some embodiments, a hybrid transceiver may use a combination of EICs and PICs to transmit and receive optical signals between devices. In some embodiments, a first hybrid transceiver may bi-directionally communicate with a second hybrid transceiver using an optical interconnection.

As used herein electronic integrated circuits, or EICs, may refer to a wide variety of integrated circuits using electrical components. In some embodiments, EICs may include a combination of various electrical components such as transistors, resistors, inductors, and capacitors which in combination form an electronic circuit on a substrate. In some embodiments, EICs may include central processing units (CPUs), logic chips, memory such as static random-access memory (SRAM), dynamic random-access memory (DRAM), application processors (AP), graphical processing units (GPUs), artificial intelligence (AI) chips, high bandwidth memory (HBM) interfaces, and other application-specific integrated circuits (ASIC). In some embodiments, a combination of circuits may be present on a substrate. In some embodiments, EICs may be referred to in terms such as microchips, microcontrollers, silicon chips.

As used herein photonic integrated circuits, or PICs, may refer to a wide variety of integrated circuits using photonic components. In some embodiments, PICs may include a combination of various photonic components such as waveguides, optical filters, gratings, lenses, mirrors, and optical ring resonators. In some embodiments, PICs may include electrical components such as photodiodes, light emitting diodes, and laser diodes. In some embodiments, PICs may be referred to using terms such as integrated optical circuits, and planar light wave circuits.

As used herein substrates may refer to a variety of materials and structures, including wafers using silicon, wafers using silicon on an insulator (SOI) such as glass, wafers of other semiconductor materials such as germanium, as well as other semiconductor materials on an insulator. In some embodiments, a substrate may include an organic material. In some embodiments, the substrates may be referred to as wafers, dies, and chips alone or in combination. In some embodiments, a substrate for use in a PIC may be referred to a waveguide. Bonding substrates may be thus known in some embodiments as die-to-die (D2D) bonding, wafer-to-wafer bonding (W2W) or die-to-wafer bonding (D2W). In some embodiments, a packaged chip may contain multiple substrates, and may include PIC substrates, EIC substrates, or a combination of PIC substrates and EIC substrates. In some embodiments, circuits may be bonded directly facing each other, while in other embodiments a flip-chip bonding may be used. In some embodiments, interconnections may be made between substrates on a front or circuit side of the substrate. In other embodiments, interconnections may be made on a rear or back side of the substrate opposite from the circuit structure. In some embodiments, an interconnection may include through-silicon vias (TSVs) or other forms of through-chip vias where one or more substrates may be connected using a via traveling through an interposer such as another substrate or chip. In some embodiments, an interconnection may be formed using connections on a surface of a substrate, such as a pad, and may use additional materials between the pads such as solder to form an interconnection.

In some embodiments, bonding between substrates may involve bonding between metals, or metal-metal bonding. In some embodiments, bonding between substrates may involve bonding between dielectric materials, or dielectric-dielectric bonding. In some embodiments, bonding between substrates may involve both metal-metal and dielectric-dielectric bonding, known as hybrid bonding. A hybrid bonding technique may be used to provide additional connections between opposing surfaces, allowing both dielectric and conductive surfaces to bond, and may increase the mechanical strength of the resulting structure.

As used herein multiplexing may refer to a number of techniques for multiplexing optical signals. In some embodiments, multiplexing may refer to wavelength division multiplexing (WDM). In some embodiments, the multiplexing may refer to polarization-based multiplexing. In some embodiments, the multiplexing may refer to optical fiber mode based polarization. In some embodiments, multiplexing may be a combination of one or more of WDM, polarization, and fiber mode polarization.

As used herein, polarization may refer to both linear and circular polarization. Linear polarization modes may be referred to as S and P or transverse-magnetic (TM) and transverse-electric (TE) polarizations. Circular polarizations may be referred to as right-handed polarization (RCP) or left-handed polarization (RCP).

As used herein, a nanostructured layer is a layer such as a thin film layer having one or more structures in the nanometer (nm) region, the structures having dimensions of approximately 1 nm to 1,000 nm. The nanostructure layer may comprise a single individual structure, or may comprise a plurality of structures. The nanostructure layer may comprise an array of individual nanostructures, with the individual nanostructures having one or more shapes, such as rods, cylinders, circles, squares, rectangles, or any other suitable shape. In some embodiments, an array of nanostructures may form a repeating pattern where the orientation, shape, and size may alter between nanostructures. In some embodiments, the nanostructured layer may form a metastructure such as a metalens. In some embodiments, the nanostructured layer may form a grating structure. In some embodiments, the nanostructure layer may be a plurality of layers, and may include additional optical elements in conjunction with nanostructures. The additional optical elements may include multiple thin-film optical coatings like Bragg filter coatings, diffractive coatings, polarizing coatings, and anti-reflective coatings.

In some embodiments, nanostructures may split an incoming light beam into multiple light beams. In some embodiments, the nanostructures may split the same and/or different wavelengths in different locations using the grating equation, and may use the wavelength dispersive properties of metastructures. In some embodiments, nanostructures may split polarizations based on the size of the nanostructures and their geometry. In some embodiments, Bragg filters may be incorporated to further disperse wavelengths based on resonance conditions.

Disclosed herein are various embodiments of systems, methods and devices using hybrid transceivers incorporating both EIC and PIC components. In some embodiments, the hybrid transceiver may provide a low-noise and high-bandwidth performance receiver. In some embodiments, the hybrid transceiver may incorporate a photodetector within an EIC. In some embodiments, an EIC with an incorporated photodetector may have a separate fiber connection from the PIC, while in other embodiments, the EIC and the PIC may share a fiber connector. In some embodiments, a metastructure such as a grating may be used as an optical multiplexer to multiplex an optical signal, or in other embodiments the metastructure may be used as an optical demultiplexer to demultiplex an optical signal. In some embodiments, the optical multiplexer may be incorporated in the EIC, while in other embodiments, the optical multiplexer may be incorporated within the PIC. In some embodiments, part of a Transimpedance Amplifier (TIA) may be formed in the PIC, including components such as input transistors and resistors. In some embodiments, the entire TIA may be formed on the EIC. In some embodiments, the EIC and the PIC may be bonded using copper-copper (Cu—Cu) bonding, and in some embodiments may further include a dielectric bonding process to create a hybrid bond.

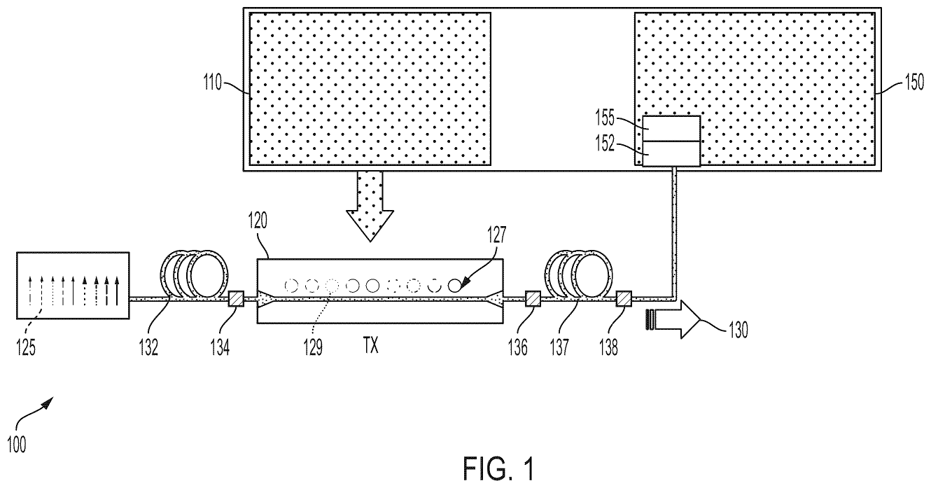

FIG. 1 discloses an exemplary embodiment of an architecture for a first optical communication system 100. The first optical communication system 100 includes a transmitter EIC 110, a transmitter PIC 120 and a receiver EIC 150 which communicate via an optical signal 130. The optical signal 130 is generated by a light source which may take the form of a laser comb source 125. The laser comb source 125 may take the form of a four-wave-mixing-based frequency comb, a Kerr frequency comb, or any other suitable technique for generating a comb signal. As used herein, a comb signal refers to an optical signal having a plurality of wavelengths separated into discrete spectra. The optical signal 130 travels from the laser comb source 125 via a first optical fiber 132 to the transmitter PIC 120. In some embodiments, a first fiber link 134 may connect between the first optical fiber 132 and the transmitter PIC 120. In some embodiments, the first fiber link 134 may take the form of a pluggable optical connector or plug connector. In the transmitter PIC 120, the optical signal 130 may be modulated and adjusted by photonic elements embedded within the transmitter PIC 120, including micro-ring resonators, phase shifts, couplers, lenses, polarizers, mirrors, delay lines, and a variety of other photonic elements both passive and active. In the exemplary embodiment of FIG. 1, the transmitter PIC 120 includes a modulator 127 containing one or more micro-ring resonators 129. The one or more micro-ring resonators 129 may include micro-ring resonators designed to modulate a specific spectrum from the laser comb source 125, with a plurality of micro-ring resonators allowing some or all of the comb of spectra from the laser comb source 125 to be modulated. In addition, additional modulation elements may be used, for example, to apply a modulation based on fiber mode or polarization.

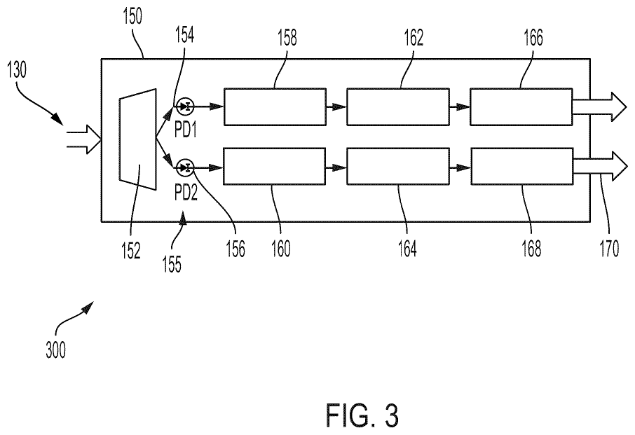

The transmitter EIC 110 provides the driving electronics for the transmitter PIC 120, and the transmitter EIC 110 may include heater control circuits, heater drivers, modulator drivers, and serializers to modify the optical signal 130 being transmitted via the transmitter PIC 120. For example, if the transmitter PIC 120 includes one or more micro-ring resonators 129, heaters may be integrated with the one or more micro-ring resonators 129 to provide control over the resonance frequency of the one or more micro-ring resonators 129 by altering the physical characteristics of the one or more micro-ring resonators 129. While portions of the heaters may be formed within the transmitter PIC 120, the electronics controlling and regulating the heaters are within the transmitter EIC 110. Additional details of the transmitter EIC 110 will be discussed further below, for example in FIG. 3.

From the transmitter PIC 120, the optical signal 130 is transmitted, for example, via a second optical fiber 137, to the receiver EIC 150. In some embodiments, a second fiber link 136 may connect the transmitter PIC 120 to the second optical fiber 137, and a third fiber link 138 may connect the second optical fiber 137 to the receiver EIC 150. In some embodiments, the second fiber link 136 and/or the third fiber link 138 may take the form of a pluggable fiber connector.

The optical signal 130 is received in the receiver EIC 150 by an optical demultiplexer 152. The optical demultiplexer 152 may include at least one nanostructured layer. The optical demultiplexer 152 separates the optical signals 130 into a plurality of demultiplexed optical signals which are transmitted to a photodetector array 155. At the photodetector array 155, the plurality of demultiplexed optical signals may be spread out across the array, allowing individual photodetectors to separately read the individual optical signals of the plurality of demultiplexed optical signals. The receiver EIC 150 may include additional supporting electronics for interpreting the received signals, including receivers, amplifiers, comparators, analog-to-digital converters (ADCs), deserializers, and supporting processors. The electronics of the receiver EIC 150 are discussed in further depth below, for example in FIG. 3.

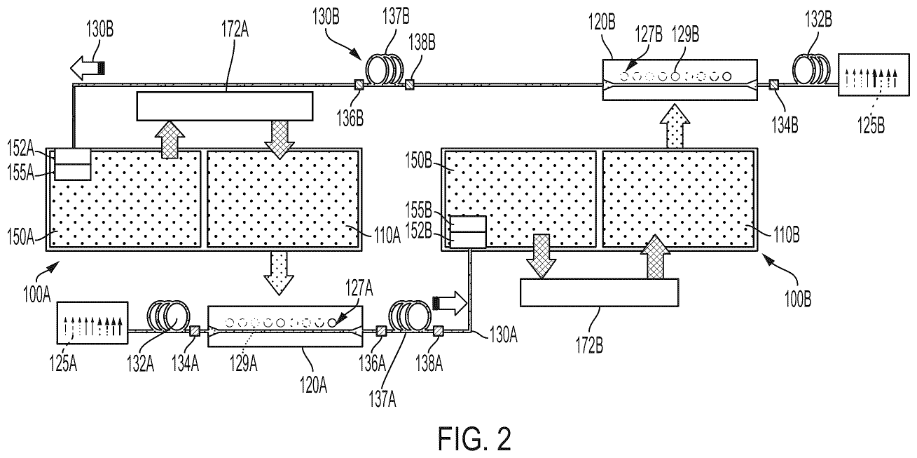

FIG. 2 discloses an exemplary embodiment of a pair of optical communications systems in optical communication, including a first optical communications system 100A and a second optical communications system 100B. The first optical communications system 100A and the second optical communications system 100B may take the form of the first optical communication system 100. Thus, components of the first optical communications system 100A are labeled with the same reference numerals as described in FIG. 1 and appended with the letter “A” while and components of the second optical communications system 100B are labeled with the same reference numerals as described in FIG. 1 the second optical communications system 100B and appended with the letter “B”. The first optical communications system 100A may be arranged to transmit signals to the second optical communications system 100B, while the second optical communications system 100B may be arranged to transmit signals to the first optical communications system 100A.

Each of the first optical communications system 100A and second optical communications system 100B has a laser comb source 125A/125B providing an optical signal 130A/130B via a first optical fiber 132A/132B to the transmitter PIC 120A/120B. In some embodiments, a first fiber link 134A/134B may connect between the first optical fiber 132A/132B and the transmitter PIC 120A/120B. In some embodiments, the first fiber link 134A/134A may take the form of a pluggable optical connector. In the transmitter PIC 120A/120B, the optical signal 130A/130B may be modulated and adjusted by photonic elements embedded within the transmitter PIC 120A/120B, including micro-ring resonators, phase shifts, couplers, lenses, polarizers, mirrors, delay lines, and a variety of other photonic elements both passive and active. In the exemplary embodiment of FIG. 2, the transmitter PIC 120A/120B includes a modulator 127A/127B containing one or more micro-ring resonators 129A/129B. The one or more micro-ring resonators 129A/129B may include micro-ring resonators designed to modulate a specific spectrum from the laser comb source 125A/125B, with a plurality of micro-ring resonators allowing some or all of the comb of spectra from the laser comb source 125A/125B to be modulated. In addition, additional modulation elements may be used, for example, to apply a modulation based on fiber mode or polarization.

The transmitter EIC 110A/110B provides the driving electronics for the transmitter PIC 120A/120B, and the transmitter EIC 110A/110B may include heater control circuits, heater drivers, modulator drivers, and serializers to modify the optical signal 130A/130B being transmitted via the transmitter PIC 120A/120B. For example, if the transmitter PIC 120A/120B includes one or more micro-ring resonators 129A/129B, heaters may be integrated with the one or more micro-ring resonators 129A/129B to provide control over the resonance frequency of the one or more micro-ring resonators 129A/129B by altering the physical characteristics of the one or more micro-ring resonators 129A/129B. While portions of the heaters may be formed within the transmitter PIC 120A/120B, the electronics controlling and regulating the heaters may be within the transmitter EIC 110A/110B.

From the transmitter PIC 120A/120B, the optical signal 130A/130B is transmitted, for example, via a second optical fiber 137A to the receiver EIC 150B and via a second optical fiber 137B to the receiver EIC 150A In some embodiments, a second fiber link 136A/136B may connect the transmitter PIC 120A/120B to the second optical fiber 137A/137B, and a third fiber link 138A/138B may connect the second optical fiber 137A/137B to the receiver EIC 150A/150B. In some embodiments, the second fiber link 136A/136B and/or the third fiber link 138A/138B may take the form of a pluggable fiber connector.

The optical signal 130A/130B may be received in the receiver EIC 150A/150B by an optical demultiplexer 152A/152B. The optical demultiplexer 152A/152B may include at least one nanostructured layer. The optical demultiplexer 152A/152B may separate the optical signals 130A/130B into a plurality of demultiplexed optical signals which may be transmitted to a photodetector array 155A/155B. At the photodetector array 155A/155B, the plurality of demultiplexed optical signals may be spread out across the array, allowing individual photodetectors to separately read the individual optical signals of the plurality of demultiplexed optical signals. The receiver EIC 150A/150B may include additional supporting electronics for interpreting the received signals, including receivers, amplifiers, comparators, deserializers, ADCs, and supporting processors.

FIG. 2 also depicts a first host 172A in communication with the first optical communications system 100A and a second host 172B in communication with the second optical communications system 100B. Each of the first host 172A and the second host 172B may include a switch, a GPU, a CPU, and/or another auxiliary processing unit (xPU). The first host 172A and the second host 172B may be coupled to receive communication from the receiver EIC 150A/150B, and may be coupled to transmit communications to the transmitter EIC 110A/110B. Additionally, in some embodiments, the first host 172A and the second host 172B may communicate with the laser comb source 125A/125B either directly or via the transmitter EIC 110A/110B to control the light source and provide another source of modulation.

FIG. 3 depicts an exemplary embodiment of an architecture for an optical receiver system 300. The optical receiver system 300 may comprise the components of the receiver portion of the first optical communication system 100 with the additional inclusion of further details of the receiver EIC 150. A multiplexed optical signal 130 may be transmitted, for example, via an optical fiber, to the receiver EIC 150. The multiplexed optical signal 130 is received in the receiver EIC 150 by an optical demultiplexer 152. The optical demultiplexer 152 may include at least one nanostructured layer. The nanostructured layer of the optical demultiplexer 152 may separate the multiplexed optical signal 130 into multiple optical signals, and may transmit the optical signals to a photodetector array 155 including transmitting a first optical signal to a first photodetector 154, and transmitting a second optical signal to a second photodetector 156. At the first photodetector 154, a first electrical signal is generated and transmitted to a first Transimpedance Amplifier (TIA) 158 for amplification. In some embodiments, the first TIA 158 may include an additional amplifier. At the second photodetector 156, a second electrical signal is generated and transmitted to a second TIA 160 for amplification. The first TIA 158 and the second TIA 160 transmit the first electrical signal and second electrical signal, respectively, to a first analog-to-digital converter (ADC) 162 and a second ADC 164 to convert the analog signals into digital signals. In some embodiments a comparator may be used alongside or in place of an ADC. The digital signals from the first ADC 162 and the second ADC 164 are then transmitted to a third digital processor 166 and a fourth digital processor 168, respectively. From the third digital processor 166 and the fourth digital processor 168, outgoing signals 170 may be further transmitted to additional electrical components such as a host. The outgoing signals 170 may represent a data signal or other form of communications signal.

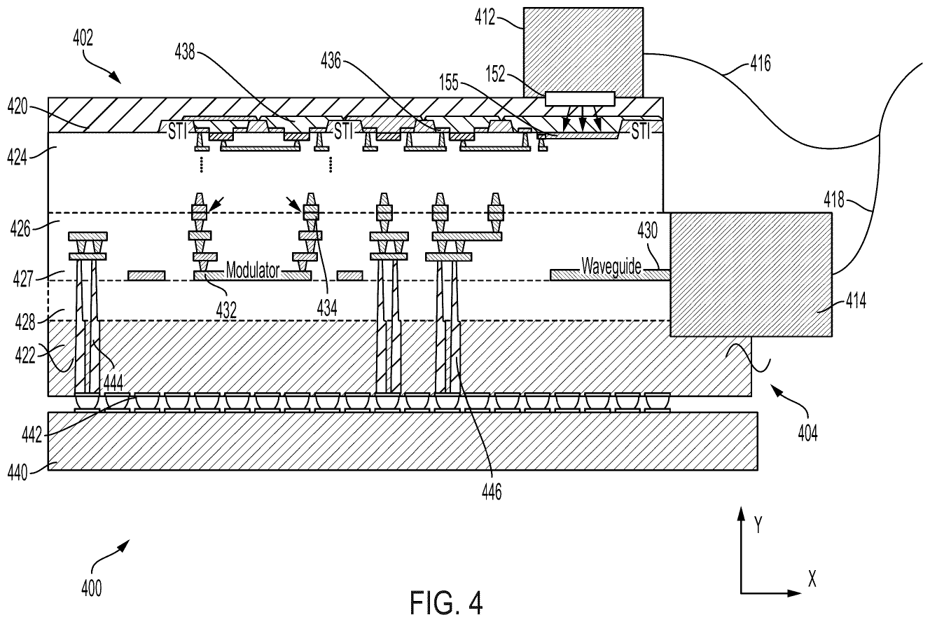

FIG. 4 depicts a cross-sectional view of an exemplary embodiment of a first monolithic hybrid transceiver 400. FIG. 4 provides a more detailed look at the structure of the first monolithic hybrid transceiver 400 including an EIC 402 and a PIC 404. In some embodiments, the EIC 402 may include the functions of both the transmitter EIC 110 and the receiver EIC 150 on a single EIC substrate 420, while in some embodiments, multiple EIC substrates may be used. In some embodiments, the PIC 404 may include the functions of both the transmitter PIC 120 as well as a receiver PIC on a single PIC substrate 422, while in some embodiments, multiple PIC substrates may be used. In FIG. 4, the transmission and receiver pathways may be split, with a receiver fiber link 412 coupled to the EIC 402 and a transmitter fiber link 414 coupled to the PIC 404. The receiver fiber link 412 and the transmitter fiber link 414 may be a pluggable optical fiber connector. As used herein, a pluggable optical fiber connector is an interface module allowing an optical fiber to be plugged directly to an optical interface. A pluggable optical fiber connector may include attachment mechanisms to allow for optical fibers to be easily connected and disconnected. A receiver fiber 416 may connect to the receiver fiber link 412, and a transmitter fiber 418 may connect to the transmitter fiber link 414. In some embodiments, the receiver fiber 416 and the transmitter fiber 418 may be part of a larger fiber bundle, while in other embodiments, the fibers may join at a splitter. In some embodiments, the splitter may incorporate a nanostructure layer to split the light based on at least one of wavelength and polarization, while in other embodiments band filters and polarization filters may be used. In some embodiments, each of the receiver fiber 416 and the transmitter fiber 418 may be a single mode fiber, a multi-mode fiber, a polarization dependent fiber, a polarization independent fiber, pluggable optical fibers, etc. Pluggable optical fibers may include a connection mechanism on a terminal end to allow for optical fibers to be easily connected and disconnected from a fiber optic connector.

In some embodiments, such as the exemplary embodiment of FIG. 4, the first monolithic hybrid transceiver 400 may have the receiver fiber link 412 mounted upon the rear of the EIC substrate 420, with the optical demultiplexer 152 aligned to receive optical signals from the receiver fiber link 412. In some embodiments, the optical demultiplexer 152 may cause the received optical signal to separate by at least one of wavelength and polarization to form a separated optical signal, while in other embodiments, additional separations may take place. In some embodiments, the separated optical signal diverges in the distance between the optical demultiplexer 152 and the photodetector array 155. In some embodiments, the photodetector array 155 may be arranged such that the photosensitive surface is mounted towards the EIC substrate 420.

In some embodiments, the optical demultiplexer 152 may be spaced from the photodetector array 155 with additional thin film optical coating layers or may directly contact the photodetector array 155. The thin film optical coating layers may include one or more optical elements such as polarizers, gratings, anti-reflection coatings, filters, etc. The optical demultiplexer 152 may split the incoming optical signal into a plurality of demultiplexed signals based on one or more of polarization, wavelength, and optical fiber mode. In some embodiments, the optical demultiplexer 152 may use at least one nanostructured layer to split the incoming optical signal into the plurality of demultiplexed signals. In some embodiments, the photodetector array 155 may have the individual photodetectors spaced apart to receive distinct portions of plurality of demultiplexed signals. For example, the optical demultiplexer 152 may generate a dispersion pattern such that different wavelengths, polarizations, and/or modes of light may be spread across the face of the photodetector array 155. In such cases, the individual photodetectors of the photodetector array 155 may thus receive a different portion of the incoming signal, allowing sensing of the demultiplexed light. The optical demultiplexer 152 may further divide separated signals into additional divisions, with a first separated signal being divided into a first divided signal and a second divided signal. The division may take place upon a second form of modulation, for example, first separating the multiplexed signal based on wavelength before dividing the separated signals based on polarization or fiber mode.

In some embodiments, individual photodetectors of the photodetector array 155 may be shown in a 2-D array of N rows by M columns. However, a photodetector array may vary in both shape and size. In some embodiments, the photodetector array 155 may be a linear array, a circular array, etc. In some embodiments, the number of photodetectors of the photodetector array 155 may comprise an M×N grid having M photodetectors per column and N photodetectors by row. M may vary from 1 to 200 or more, and N may also vary from 1 to 200 or more. The shape and size of the individual photodetectors may vary, as well as the type for photodetectors. For example, in some embodiments, the individual photodetectors may comprise photodiodes, avalanche photodiodes, phototransistors, and solaristors. In some embodiments, a photodetector may be made using inline processing as part of an integrated circuit.

In the exemplary embodiment of FIG. 4, the first monolithic hybrid transceiver 400 may have the transmitter fiber link 414 mounted against the PIC 404 and aligned to an internal waveguide 430 for transmitting the optical transmission signal. In some embodiments, the transmitter fiber link 414 may be mounted along the side of the PIC 404, while in other embodiments, the transmitter fiber link 414 may be mounted above or below the PIC 404, using any suitable technique to redirect light from the PIC 404. In some embodiments, upon the single PIC substrate 422, a layer of buried oxide, known as a BOX layer 428 may be formed. In some embodiments, the BOX layer 428 may be formed of silicon dioxide, although in other embodiments, any other suitable material may be used. In some embodiments, the BOX layer 428 may be a photonic device layer 427 where the photonic components of the PIC 404 may be formed, while in other embodiments, the BOX layer 428 may include multiple layers with the components of the PIC 404 spread on one or more of them. The PIC 404, may, in some embodiments, include components for modulating the optical signals such as micro-ring resonators, phase shifters, couplers, lenses, polarizers, mirrors, delay lines, and a variety of other photonic elements both passive and active. In the exemplary embodiment of FIG. 4, the PIC 404 includes a modulator 432 containing one or more micro-ring resonators. The modulator 432 may include micro-ring resonators designed to modulate a specific spectrum from the laser comb source 125, with a plurality of micro-ring resonators allowing some or all of the comb of spectra from the laser comb source 125 to be modulated. In addition, additional modulation elements may be used, for example, applying a modulation based on fiber mode or polarization.

In some embodiments, the EIC 402 may include receiver circuits 436 and transmitter circuits 438, while in other embodiments one or both of the circuits may be spread across multiple substrates. In some embodiments, the receiver circuits 436 may include the components of the optical receiver system 300, including a TIA, ADC, filters, and any other suitable elements, which may be coupled to the photodetector array 155. In some embodiments, the transmitter circuits 438 may be those of the transmitter EIC 110, and may include heater control circuits, heater drivers, modulator drivers, and serializers to modify the optical signal being transmitted via the PIC 404. For example, if the PIC 404 includes one or more micro-ring resonators in the modulator 432, heaters may be integrated with the one or more micro-ring resonators to provide control over the resonance frequency of the one or more micro-ring resonators by altering the physical characteristics of the one or more micro-ring resonators of the modulator 432.

In some embodiments, additional layers may exist between the EIC substrate 420 and the single PIC substrate 422, including one or more EIC interconnection layers 424, and one or more PIC backend metallization layers 426. However, in some embodiments, the EIC substrate 420 may be mounted using a flip chip design and eliminate at least one of the one or more EIC interconnection layers 424 and one or more PIC backend metallization layers 426. In some embodiments, the one or more EIC interconnection layers 424 and the one or more PIC backend metallization layers 426 may formed in a passivation material, such as silicon dioxide, while in other embodiments any other suitable material may be used. In some embodiments, the material of the one or more EIC interconnection layers 424 and the one or more PIC backend metallization layers 426 may be formed of the same materials as the BOX layer 428. In some embodiments, the one or more EIC interconnection layers 424 may provide a routing between components on the EIC 402, between the EIC 402 and the PIC 404, between the EIC 402 and exterior circuits, and combinations thereof. In some embodiments, the one or more PIC backend metallization layers 426 may provide routing between components on the PIC 404, between the EIC 402 and PIC 404, between the PIC 404 and external circuits, and combinations thereof.

In the exemplary embodiment of FIG. 4, the first monolithic hybrid transceiver 400 may mount the EIC 402 and the PIC 404 upon a package substrate 440. The package substrate 440 may, in some embodiments, include a die or wafer, while in other embodiments, an organic substrate, a printed circuit board, or any other suitable form of substrate may be used. Electrical signals may be provided via the package substrate 440 to the EIC 402 and the PIC 404 using one or more vias. The PIC substrate 422 may be attached using an interconnection 442 to the package substrate 440, and may include a conductive connection, such as bumps, microbumps, pillars, balls, and other forms such as controlled-collapse chip connection (C4) bumps, alone or in combination. As used herein, a C4 bump refers to a form of solder bumps placed on pads on a top surface of a substrate prior to flipping the substrate to form a flip-chip. The interconnection 442 may further include a dielectric material, which may include a material such as an adhesive, resin, or elastomer which may form a connection between the PIC substrate 422 and the package substrate 440 in addition to a conductive connection. In some embodiments, the dielectric material may take the form of an underfill material, while in other embodiments any suitable form may be used. In some embodiments, the combination of a conductive connection and a dielectric connection may form a hybrid bond. In some embodiments, a hybrid connection may provide a lower parasitic resistance between the EIC 402 and the PIC 404 than a metal-metal connection alone.

In the exemplary embodiment of FIG. 4, the first monolithic hybrid transceiver 400 may include one or more PIC vias 444 extending between the interconnection 442 and the one or more PIC backend metallization layers 426. In some embodiments, the one or more PIC vias 444 may provide communications or power directly from the package substrate 440, while in other embodiments, communications or power may be routed via the EIC 402. In some embodiments, one or more EIC vias 446 may extend between the interconnection 442 and the one or more EIC interconnection layers 424. The one or more EIC vias 446 may provide communications or power from the package substrate 440 to the EIC 402, and be routed using the one or more EIC interconnection layers 424 to the receiver circuits 436 and the transmitter circuits 438. In some embodiments, signals between the EIC 402 and the PIC 404 may be routed using interconnects 434, which may be formed between the one or more EIC interconnection layers 424 and the one or more PIC backend metallization layers 426, while in other embodiments, the interconnects 434 may be formed directly between the EIC 402 and the PIC 404. In some embodiments, the interconnects 434 may be formed using a metal-metal connection such as copper-copper, or any other suitable metal. In some embodiments, the material of the one or more EIC interconnection layers 424 and the one or more PIC backend metallization layers 426 may include a dielectric material such as silicon dioxide, or any other suitable dielectric, with the interconnects 434 incorporating a dielectric-dielectric bond. In some embodiments, the interconnects 434 may incorporate both a metal-metal bond and a dielectric-dielectric bond to form a hybrid bond.

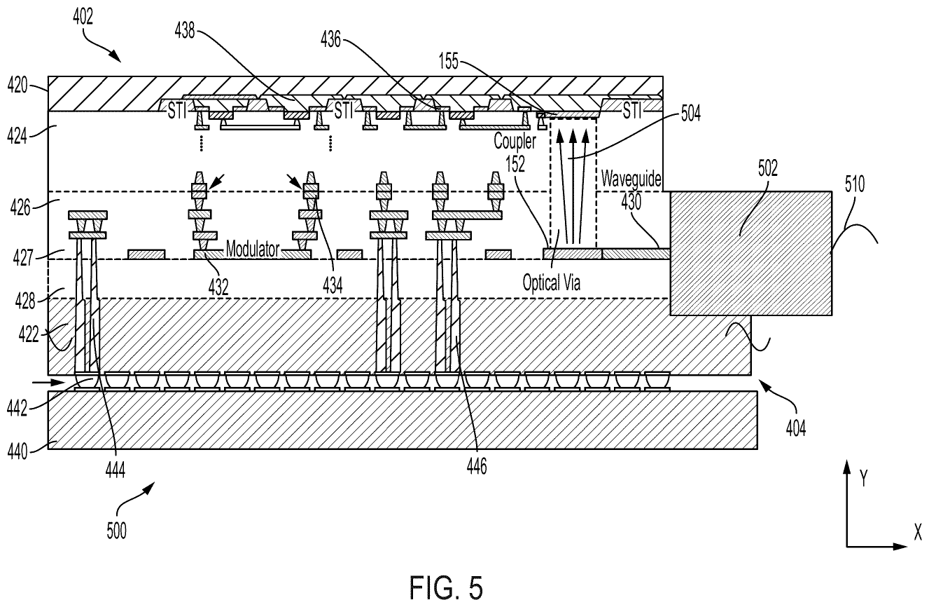

FIG. 5 depicts a cross-sectional view of an exemplary embodiment of a second monolithic hybrid transceiver 500. The second monolithic hybrid transceiver 500 of FIG. 5 differs from the first monolithic hybrid transceiver 400 of FIG. 4 by using a transceiver fiber link 502 coupling the second monolithic hybrid transceiver 500 to a transceiver fiber 510 in place of the receiver fiber link 412 coupling to the receiver fiber 416 and the transmitter fiber link 414 coupling to the transmitter fiber 418. The transceiver fiber link 502 may be a pluggable optical fiber connector, as described above with respect to the receiver fiber link 412 and the transmitter fiber link 414. In some embodiments, the transceiver fiber 510 may provide to the transceiver fiber link 502 a multiplexed optical signal using a method such as WDM, or any other suitable method of multiplexing. The multiplexed optical signal may be provided in turn to the internal waveguide 430 for distribution within the PIC 404. In some embodiments, the internal waveguide 430 may also provide the optical transmission signal which is sent out via the transceiver fiber link 502 and the transceiver fiber 510. In the exemplary embodiment of FIG. 5, the transceiver fiber link 502 is depicted as mounted on the side of the PIC 404 and aligned to the internal waveguide 430. However, in some embodiments, the transceiver fiber link 502 may be mounted to the base of the PIC 404, below the PIC 404, or alongside the EIC 402, or above the EIC 402, and additional redirection elements may be provided to route the optical signal to the internal waveguide 430.

In some embodiments, the transceiver fiber 510 may be a single mode fiber, a multi-mode fiber, a polarization dependent fiber, a polarization independent fiber, pluggable optical fibers, etc. Pluggable optical fibers may include a connection mechanism on a terminal end to allow for optical fibers to be easily connected and disconnected from a fiber optic connector.

In the exemplary embodiment of FIG. 5, the second monolithic hybrid transceiver 500 may incorporate the optical demultiplexer 152 within the PIC 404. The optical demultiplexer 152 may separate the incoming multiplexed optical signal into a separated optical signal. In some embodiments, the optical demultiplexer 152 may separate the incoming multiplexed optical signal by diverging the signal by wavelength, polarization, mode or other suitable method. In some embodiments, the separated optical signal may then travel via the optical via 504 to the photodetector array 155, while in other embodiments, additional redirection elements, filters, modulators or other optical elements may be between the optical demultiplexer 152 and the photodetector array 155. The optical via 504 may provide a distance suitable for allowing the separated optical signal from the optical demultiplexer 152 to diverge before reaching the photodetector array 155.

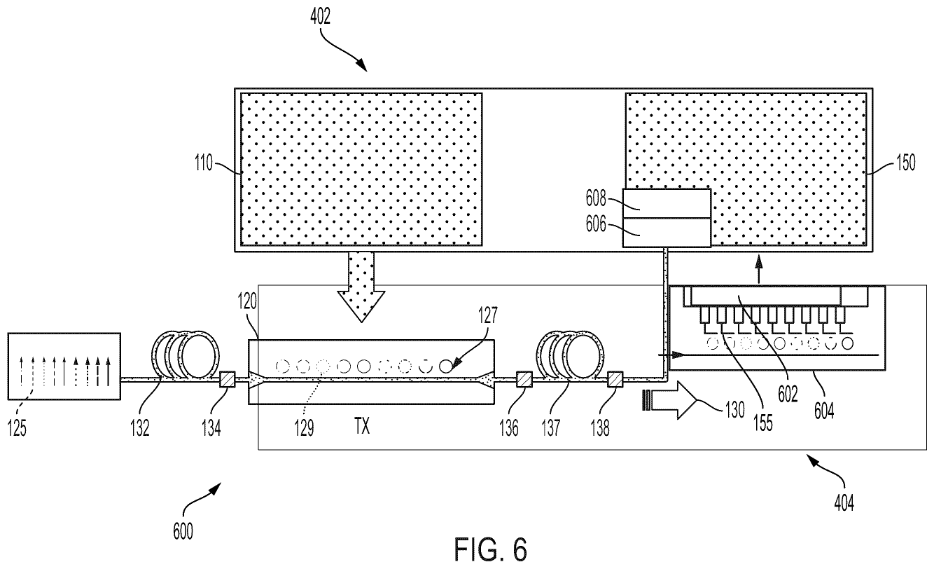

FIG. 6 depicts a plan view of an exemplary embodiment of a second optical communications system 600. The second optical communications system 600 differs from the first optical communications system 100 of FIG. 1 by including a PIC receiver 604 incorporating the photodetector array 155 and a first portion 602 of the TIA. The first portion 602 of the TIA includes parts of the TIA such as input transistors and resistors at initial stage which are formed as part of the PIC receiver 604. In some embodiments, the first portion 602 of the TIA may be formed during the creation of the PIC receiver 604 using a suitable process such as SOI, or any other appropriate process. A second portion 606 of the TIA may, in some embodiments, be formed on the receiver EIC 150, while in other embodiments the second portion 606 may be formed as part of a unitary EIC or across multiple EIC. In some embodiments, the first portion 602 of the TIA may provide signals to the second portion 606 of the TIA, and may include bias signals, sense signals, as well as any other suitable signal for the TIA input. In some embodiments, the signals may be in the form of voltages, such as bias voltage, and sense voltage, as well as any other appropriate voltages.

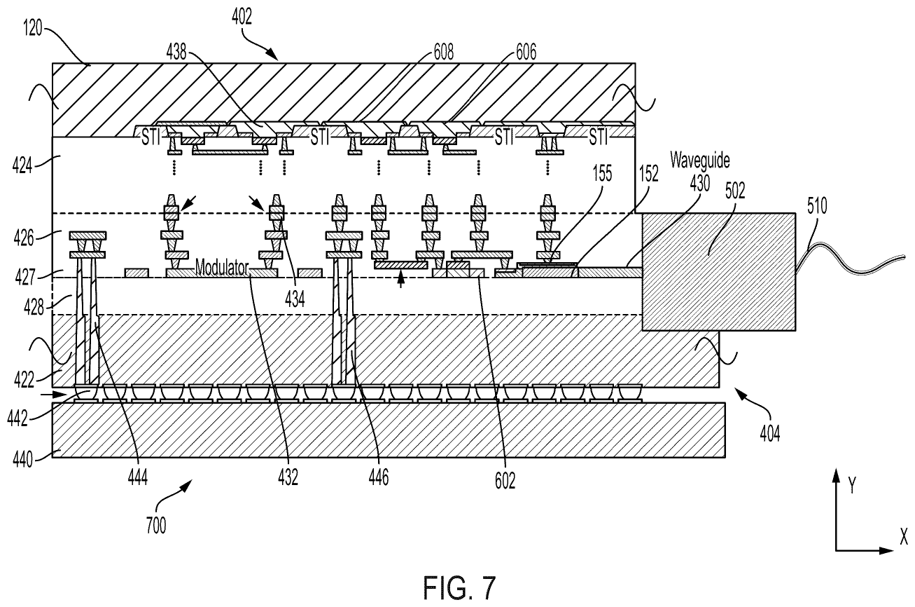

FIG. 7 discloses a cross-sectional view of an exemplary embodiment of the third monolithic hybrid transceiver 700 for use in the second optical communications system 600. The third monolithic hybrid transceiver 700 differs from the first monolithic hybrid transceiver 400 of FIG. 4 and the second monolithic hybrid transceiver 500 of FIG. 5 by incorporating the PIC receiver 604 into the PIC 404, including the photodetector array 155 and the first portion 602 of the TIA. In the exemplary embodiment of FIG. 7, the third monolithic hybrid transceiver 700, like the second monolithic hybrid transceiver 500 of FIG. 5, may use only the transceiver fiber link 502 to couple both the transmission optical signal and the receiver optical signal. However, the third monolithic hybrid transceiver 700 may place the photodetector array 155 within the PIC 404. In some embodiments, the photodetector array 155 may be spaced apart from the optical demultiplexer 152, while in others, one or more other techniques may be used to diverge the optical signal between the optical demultiplexer 152 and the photodetector array 155. In some embodiments, the photodetector array 155 may comprise one or more photodetectors coupled in turn to one or more TIAs, such as discussed with respect to the optical receiver system 300. As such, in some embodiments, the first portion 602 of TIA and the second portion 606 of TIA may refer to one or more TIA portions, with each first portion 602 of TIA and each second portion 606 of TIA combining to form a corresponding one or more TIA for the photodetectors of the photodetector array 155. The signals from the first portion 602 of TIA in the PIC 404 may be routed to the second portion 606 of TIA in the EIC 402, with the remaining portions 608 of the receiver circuits 436 receiving the amplified signal from the second portion 606 of TIA. In some embodiments, the presence of the first portion 602 of TIA in the PIC 404 reduces losses experienced by the amplifier as a whole, and may thus decrease the noise experienced by the second optical communications system 600. In some embodiments, the use of metal-metal coupling such as Cu—Cu coupling, or any other suitable metal may further reduce noise experienced by the circuitry.

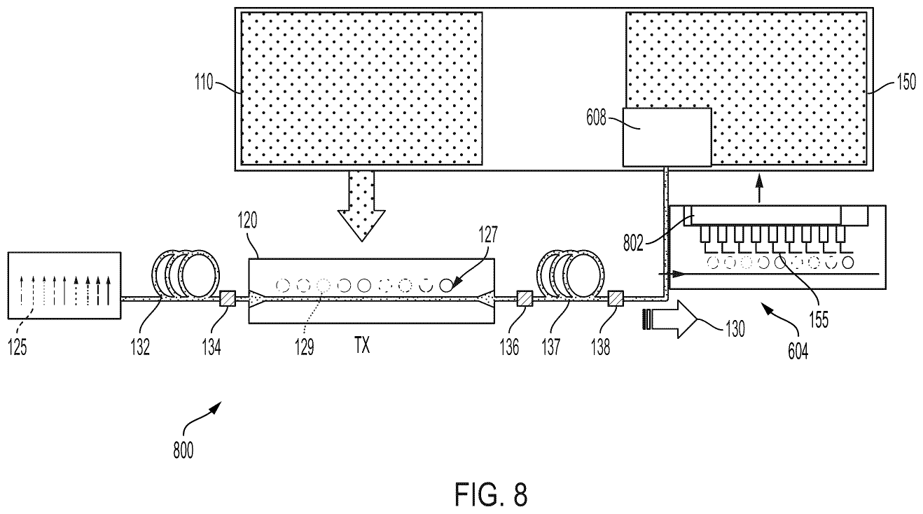

FIG. 8 depicts a plan view of an exemplary embodiment of a third optical communications system 800. The third optical communications system 800 differs from the first optical communications system 100 of FIG. 1 and the second optical communications system 600 of FIG. 6 by incorporating the entirety of a PIC TIA 802 on the PIC receiver 604. As such, in the exemplary embodiment of FIG. 8, the third optical communications system 800 has only the remaining portions of the receiver circuits 608 receiving the amplified signal from the PIC TIA 802.

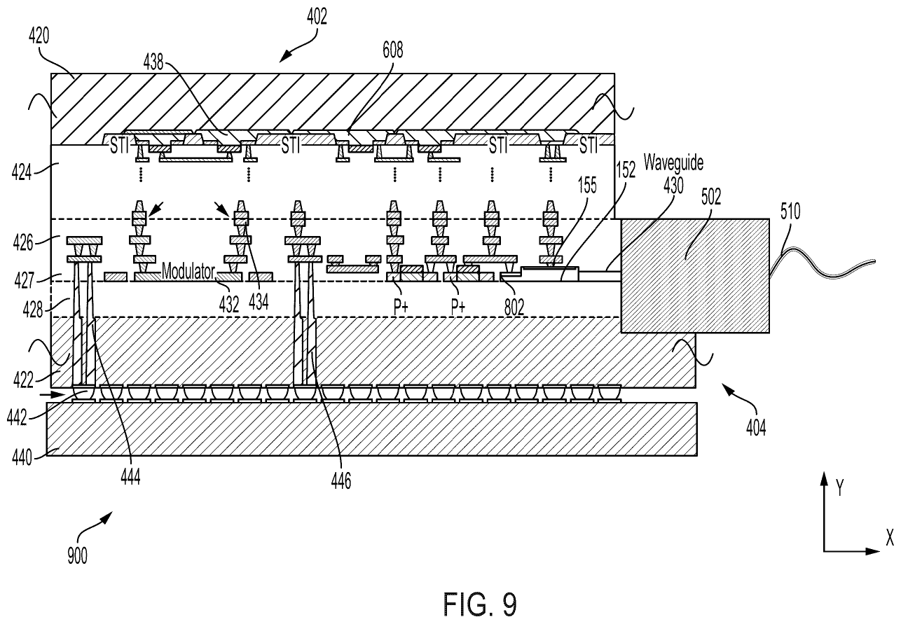

FIG. 9 depicts a cross-sectional view of an exemplary embodiment of a fourth monolithic hybrid transceiver 900 for use in the third optical communications system 800. The fourth monolithic hybrid transceiver 900 of FIG. 9 differs from the third monolithic hybrid transceiver 700 by having the PIC TIA 802 receive the signal from the photodetector array 155, with the resulting signal transmitted from the PIC 404 to the remaining portions of the receiver circuits 608 in the EIC 402. In some embodiments, the presence of the PIC TIA 802 in the PIC 404 reduces losses experienced by the amplifier due to distance between the PIC 404 and the EIC 402 and may thus decrease the noise experienced by the third optical communications system 800. In some embodiments, the use of metal-metal coupling such as Cu—Cu coupling, or any other suitable metal may further reduce noise experienced by the circuitry.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A device comprising:
a photonic integrated circuit;
an optical demultiplexer; and
an electronic integrated circuit mounted on the photonic integrated circuit, the electronic integrated circuit comprising at least one photodetector optically coupled to the optical demultiplexer;
the optical demultiplexer configured to separate an incoming optical signal into a first separated optical signal and a second separated optical signal; and
the at least one photodetector having a first photodetector and a second photodetector, the first photodetector to receive the first separated optical signal and the second photodetector to receive the second separated optical signal.

2. The device of claim 1, wherein the optical demultiplexer is configured to separate the first separated optical signal and the second separated optical signal by polarization.

3. The device of claim 1, wherein the optical demultiplexer is configured to separate the first separated optical signal and the second separated optical signal by wavelength.

4. The device of claim 1, wherein the optical demultiplexer is configured to separate the first separated optical signal and the second separated optical signal by optical fiber mode.

5. The device of claim 1, wherein the electronic integrated circuit includes a plug connector configured to receive an incoming optical fiber; and
wherein the incoming optical fiber is configured to transmit the incoming optical signal to the optical demultiplexer.

6. The device of claim 1, wherein the photonic integrated circuit includes a plug connector configured to receive a bi-directional optical fiber;
wherein the bi-directional optical fiber is configured to transmit the incoming optical signal to the optical demultiplexer; and
wherein the bi-directional optical fiber is configured to transmit an outgoing optical signal from the photonic integrated circuit.

7. The device of claim 1, wherein the optical demultiplexer is mounted on the photonic integrated circuit; and wherein the optical demultiplexer is configured to transmit the incoming optical signal to the at least one photodetector on the electronic integrated circuit using an optical via.

8. The device of claim 1, wherein the optical demultiplexer is mounted on the electronic integrated circuit; and wherein the optical demultiplexer is configured to transmit the incoming optical signal to the at least one photodetector along a divergence path.

9. A system comprising:
a substrate having an electronic integrated circuit and a photonic integrated circuit mounted thereon;
the photonic integrated circuit having an optical transceiver, an optical demultiplexer, a photodetector, and an at least first portion of an amplifier;
the optical transceiver configured to transmit an outgoing optical signal and receives an incoming optical signal;
the optical demultiplexer configured to demultiplex the incoming optical signal into a demultiplexed optical signal;
the photodetector configured to generate a first electrical signal from the demultiplexed optical signal and configured to transmit the first electrical signal to the at least first portion of the amplifier, the at least first portion of the amplifier configured to generate a second electrical signal; and
the electronic integrated circuit to receive the second electrical signal.

10. The system of claim 9, wherein the at least first portion of the amplifier comprises at least one member selected from the group consisting of input transistors and first stage resistors, and wherein the second electrical signal comprises at least one member selected from the group consisting of a bias voltage and signal voltage.

11. The system of claim 9, wherein the optical demultiplexer has a first nanostructured layer, the first nanostructured layer configured to separate the incoming optical signal into a first optical signal and a second optical signal; and
wherein the first optical signal and the second optical signal are separated by at least one member selected from the group consisting of wavelength, polarization, and fiber mode.

12. The system of claim 9, wherein the at least first portion of the amplifier is formed in a photonic device layer of the photonic integrated circuit.

13. The system of claim 9, wherein the at least first portion of the amplifier comprises a transimpedance amplifier formed in a photonic device layer of the photonic integrated circuit;
and wherein the second electrical signal is an amplified signal.

14. The system of claim 9,
wherein the optical demultiplexer demultiplexing the incoming optical signal into the demultiplexed optical signal further comprises the incoming optical signal separated into a first optical signal and a second optical signal;
wherein the photodetector comprises a first photodetector and a second photodetector, the first photodetector configured to receive the first optical signal and to generate a third electrical signal, the second photodetector configured to receive the second optical signal and to generate a fourth electrical signal;
wherein the at least first portion of the amplifier comprises a first at least first portion of the amplifier and a second at least first portion of the amplifier, the first at least first portion of the amplifier configured to receive the third electrical signal from the first photodetector and to generate a fifth electrical signal, the second at least first portion of the amplifier configured to receive the fourth electrical signal from the second photodetector and to generate a sixth electrical signal; and
wherein the electronic integrated circuit is configured to receive the fifth electrical signal and sixth electrical signal.

15. The system of claim 9, wherein the electronic integrated circuit comprises a second portion of the amplifier, the at least first portion of the amplifier and the second portion of the amplifier forming a transimpedance amplifier.

16. A device comprising:
a substrate having an electronic integrated circuit and a photonic integrated circuit mounted thereon;
the photonic integrated circuit having an optical demultiplexer, a photodetector, and a transimpedance amplifier;
the optical demultiplexer configured to receive an incoming optical signal and configured to split the incoming optical signal into a demultiplexed optical signal;
the photodetector configured to generate an electrical signal from the demultiplexed optical signal, and the photodetector configured to transmit the electrical signal to the transimpedance amplifier, the transimpedance amplifier configured to generate an amplified signal; and
the electronic integrated circuit configured to receive the amplified signal.

17. The device of claim 16, wherein the optical demultiplexer is configured to split the demultiplexed optical signal by polarization.

18. The device of claim 16, wherein the optical demultiplexer is configured to split the demultiplexed optical signal by wavelength.

19. The device of claim 16, wherein the optical demultiplexer is configured to split the demultiplexed optical signal by optical fiber mode.

20. The device of claim 16, wherein transimpedance amplifier is formed in a photonic device layer of the photonic integrated circuit.
